(19) United States
(12) Patent Application Publication
(10) Pub. No.: US 2006/0194436 A1
(43) Pub. Date: Aug. 31, 2006

(54) Semiconductor device including resistor and method of fabricating the same

(75) Inventors: Myoung-Hwan Oh, Yongin-si (KR); Hee-Sung Kang, Seongnam-si (KR); Choong-Ryul Ryou, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/353,348

(22) Filed: Feb. 14, 2006

(30) Foreign Application Priority Data
Feb. 28, 2005 (KR) 10-2005-0016824

(51) Int. Cl. H01L 21/302

(52) U.S. Cl. 438/689

(57) ABSTRACT

In a semiconductor device including a resistor and a method of fabricating the same, the semiconductor device includes an isolation insulating layer disposed in a semiconductor substrate to define at least two active regions spaced from each other. A well resistor pattern is disposed below the isolation insulating layer to connect the active regions. An upper resistor pattern is disposed on the isolation insulating layer between the active regions. A resistor connector electrically connects a selected one of the active regions with the upper resistor pattern so that the well resistor pattern and the upper resistor pattern are connected in series.

### RELATED APPLICATIONS

This application claims the priority of Korean Patent Application No. 2005-0016824, filed on Feb. 28, 2005, in the Korean Intellectual Property Office, the disclosure of which is incorporated herein in its entirety by reference.

### BACKGROUND OF THE INVENTION

1. Field of the Invention

The present invention relates to a semiconductor device and a method of fabricating the same, and more particularly, to a semiconductor device including a resistor having a sufficient resistance value while achieving high integration and a method of fabricating the same.

2. Description of the Related Art

Semiconductor memory devices commonly include a cell region in which a plurality of unit cells are arranged at regular intervals and a peripheral region which is located adjacent to the cell region and drives and controls the unit cells. In the peripheral region, transistors, diodes, and resistors, which drive the unit cells, are formed.

Conventionally, as a resistor formed in the peripheral region, a well resistor formed of an impurity diffusion layer in a semiconductor substrate or a polysilicon resistor formed on the semiconductor substrate has been used. Also, the well resistor and the polysilicon resistor were commonly formed in different regions of the peripheral region, and a resistor having a resistance value required for a circuit was selected and used. For example, a semiconductor device including a polysilicon resistor is disclosed in U.S. Pat. No. 4,620,212 entitled “Semiconductor device with a resistor of polycrystalline silicon” by Kazuo Ogasawara. Also, a semiconductor memory device having a polysilicon resistor formed on a peripheral region when forming a contact plug contacting a source/drain region after forming a gate electrode is disclosed in U.S. Pat. No. 6,172,389 entitled “Semiconductor memory device having a reduced area for a resistor element” by Sakoh.

On the other hand, active elements such as transistors have been continuously integrated at higher levels in order to achieve operation at increasingly rapid speeds. However, in the case of a resistor, which is a passive element, there is a limit in reducing the scale of the resistor so as to satisfy a large resistance value required for the circuit. That is, in order to obtain the large resistance value, the length of the resistor should increase. However, in this case, the ratio of the resistor area to the chip area increases and thus the total chip area increases, which is contrary to higher integration. Accordingly, a resistor employed in a highly integrated semiconductor device should have a small area and a sufficiently large resistance value.

### SUMMARY OF THE INVENTION

In order to address the aforementioned problems, the present invention provides a semiconductor device including a resistor having a reduced area and a method of fabricating the same.

The present invention also provides a semiconductor device including a resistor having a sufficiently large resistance value in a reduced area and a method of fabricating the same.

According to an aspect of the present invention, there is provided a semiconductor device including a resistor having a sufficient large resistance value and a reduced area. The semiconductor device includes an isolation insulating layer disposed in a semiconductor substrate to define at least two active regions spaced from each other. A well resistor pattern is disposed below the isolation insulating layer to connect the active regions. An upper resistor pattern is disposed on the isolation insulating layer between the active regions. A resistor connector electrically connects a selected one of the active regions with the upper resistor pattern so that the well resistor pattern and the upper resistor pattern are connected in series.

In an embodiment, the well resistor pattern may be an impurity diffusion layer doped with N-type or P-type impurity ions.

In another embodiment, the upper resistor pattern may be a polysilicon layer pattern. The polysilicon layer pattern may be doped with N-type or P-type impurity ions.

In another embodiment, the upper resistor pattern may be formed simultaneously with a polysilicon gate electrode.

In another embodiment, the well resistor pattern may have a rectangular shape having a length corresponding to a distance between the active regions and a width perpendicular to the length when viewed in a plan view. In this case, the upper resistor pattern may be disposed over the well resistor pattern and have a rectangular shape extending in the same length direction and width direction as the well resistor pattern when viewed in a plan view.

In another embodiment, at least one semiconductor region may be defined in the well resistor pattern between the active regions by the isolation insulating layer. In this case, the active regions and the at least one semiconductor region may be connected to each other through the well resistor pattern. Also, an inter-resistor insulating layer which electrically insulates the upper resistor pattern from the well resistor pattern may be disposed on the semiconductor substrate of the semiconductor region.

In another embodiment, an interlayer insulating layer may be disposed on the semiconductor substrate to cover the upper resistor pattern. In this case, the resistor connector is disposed to penetrate through the interlayer insulating layer. The resistor connector may be a resistor contact plug which penetrates through the interlayer insulating layer and contacts both the selected one of the active regions and one end portion of the upper resistor pattern adjacent to the selected one of the active regions. Alternatively, the resistor connector may include a first resistor contact plug which penetrates through the interlayer insulating layer and contacts the selected one of the active regions, a second resistor contact plug which penetrates through the interlayer insulating layer and contacts one end portion of the upper resistor pattern adjacent to the selected one of the active regions, and a resistor connecting interconnection which is disposed on the interlayer insulating layer and connects the first and second resistor contact plugs.

In another embodiment, a first interconnection contact plug which penetrates through the interlayer insulating layer and contacts the other of the active regions and a second interconnection contact plug which contacts the other end portion of the upper resistor pattern may further included. A first interconnection and a second interconnection may be disposed on the interlayer insulating layer to contact the first interconnection contact plug and the second interconnection contact plug, respectively.

According to another aspect of the present invention, there is provided a method of fabricating a semiconductor device. This method includes forming an isolation insulating layer to define at least two active regions spaced from each other in a semiconductor substrate. A well resistor pattern is formed in the semiconductor substrate below the isolation insulating layer to connect the active regions. An upper resistor pattern is formed on the isolation insulating layer between the active regions. A resistor connector is formed to connect a selected one of the active regions with one end portion of the upper resistor pattern adjacent to the selected one of the active regions so that the well resistor pattern and the upper resistor pattern are connected in series.

In an embodiment, forming the well resistor pattern may include forming a mask pattern exposing the active regions and the isolation insulating layer between the active regions, and implanting impurity ions into the semiconductor substrate using the mask pattern as an ion implantation mask.

In another embodiment, the upper resistor pattern may be formed of a polysilicon layer pattern. In this case, the upper resistor pattern may be formed simultaneously with a polysilicon gate electrode.

In another embodiment, forming the isolation insulating layer may further include defining at least one semiconductor region between the active regions. In this case, before forming the well resistor pattern, an inter-resistor insulating layer which electrically insulates the upper resistor pattern from the well resistor pattern may be formed on the semiconductor substrate of the semiconductor region.

In another embodiment, after forming the upper resistor pattern, an interlayer insulating layer may be formed on the semiconductor substrate to cover the upper resistor pattern. In this case, the resistor connector may be formed through the interlayer insulating layer.

In another embodiment, forming the resistor connector may include patterning the interlayer insulating layer to form a resistor contact hole successively exposing both the selected one of the active regions and one end portion of the upper resistor pattern adjacent to the selected one of the active regions, and forming a resistor contact plug filling the resistor contact hole. Alternatively, forming the resistor connector may include patterning the interlayer insulating layer to form a first contact hole and a second resistor contact hole exposing the selected one of the active regions and one end portion of the upper resistor pattern adjacent to the selected active region, respectively, forming a first resistor contact plug and a second resistor contact plug which fill the first resistor contact hole and the second resistor contact hole, respectively; and forming a resistor connecting interconnection on the interlayer insulating layer to connect the first resistor contact plug with the second resistor contact plug.

In another embodiment, a first interconnection contact plug which contacts the other one of the active regions through the interlayer insulating layer and a second interconnection contact plug which contacts the other end portion of the upper resistor pattern through the interlayer insulating layer may be simultaneously formed, when forming the resistor connector.

In another embodiment, after forming the upper resistor pattern, insulating spacers may be formed to cover sidewalls of the upper resistor pattern. Further, highly doped layers which are doped with impurity ions of the same conductivity type as the well resistor pattern and have an impurity concentration higher than that of the well resistor pattern may be formed in the surfaces of the active regions of the semiconductor substrate.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view of a semiconductor device including a resistor according to an embodiment of the present invention;

FIG. 2 is a cross-sectional view taken along line I-I′ shown in FIG. 1;

FIG. 3 is a plan view of a semiconductor device including a resistor according to another embodiment of the present invention;

FIG. 4 is a cross-sectional view taken along line II-II′ shown in FIG. 3;

FIG. 5 is a plan view of a semiconductor device including a resistor according to another embodiment of the present invention;

FIG. 6 is a cross-sectional view taken along line III-III′ shown in FIG. 5;

FIGS. 7 through 10 are cross-sectional views illustrating a method of fabricating a semiconductor device including a resistor according to an embodiment of the present invention;

FIG. 11 is a cross-sectional view illustrating a method of fabricating a semiconductor device including a resistor according to another embodiment of the present invention; and

FIGS. 12 and 13 are cross-sectional views illustrating a method of fabricating a semiconductor device including a resistor according to another embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. In the figures, if a layer is described as being “on” another layer or a substrate, the layer can be formed directly on another layer or a substrate, or another layer can be interposed therebetween. Like numbers refer to like elements throughout the specification.

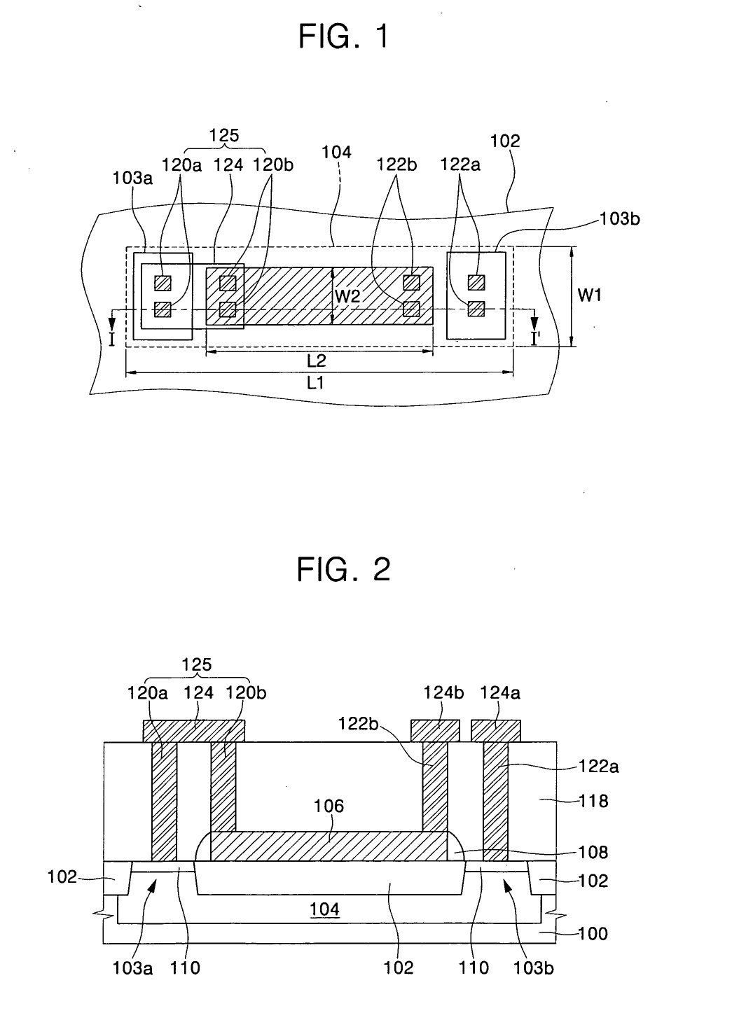

FIG. 1 is a plan view of a semiconductor device including a resistor according to an embodiment of the present invention, and FIG. 2 is a cross-sectional view taken along line I-I′ shown in FIG. 1.

Referring to FIGS. 1 and 2, an isolation insulating layer 102 is disposed in a semiconductor substrate 100. The isolation insulating layer 102 defines at least two active regions 103a and 103b spaced apart from each other. The semiconductor substrate 100 may be a silicon substrate doped with impurity ions of a first conductivity type. For example, the semiconductor substrate 100 may be a P-type silicon substrate. The isolation insulating layer 102 may be a silicon oxide layer. Hereinafter, for convenience sake, the active region shown on a left side of FIG. 1 will be referred to as a first active region 103a and the active region shown on a right side thereof will be referred to as a second active region 103b. A well resistor pattern 104 is disposed below the isolation insulating layer 102 to connect the first active region 103a and the second active region 103b. In one embodiment, the well resistor pattern 104 is disposed in a peripheral region adjacent to a cell region of the semiconductor substrate 100. The well resistor pattern 104 is an impurity diffusion layer of a second conductivity type opposite to the first conductivity type. For example, when the semiconductor substrate 100 is the P-type silicon substrate, the well resistor pattern 104 may be an N-type impurity diffusion layer such as arsenic (As), phosphorous (P), or antimony (Sb).

An upper resistor pattern 106 is disposed on the isolation insulating layer 102 between the active regions 103a and 103b. The upper resistor pattern 106 may be a polysilicon layer pattern. The polysilicon layer pattern may be doped with N-type impurity ions or P-type impurity ions. Insulating spacers 108, which are made of an insulating layer such as a silicon nitride layer, may be disposed on sidewalls of the upper resistor pattern 106.

As shown in FIG. 1, the well resistor pattern 104 may have a rectangular shape having a length L1 corresponding to a straight direction for connecting the active regions 103a and 103b to each other and a width W1 perpendicular to the length L1. However, the well resistor pattern 104 is not limited to this and may be modified to have various shapes such as a zigzag shape so as to increase the resistance value of the well resistor pattern 104. The upper resistor pattern 106 is disposed over the well resistor pattern 104 and is electrically insulated from the well resistor pattern 104 by the isolation insulating layer 102 located between the active regions 103a and 103b. The upper resistor pattern 106 may be disposed over the well resistor pattern 104 to have substantially the same shape as the well resistor pattern 104. However, the upper resistor pattern 106 is not limited to this shape and may be modified to have various shapes so as to increase the resistance value. In the case where the well resistor pattern 104 has the rectangular shape as described above, the upper resistor pattern 106 also has a rectangular shape having a length L2 and a width W2 in the same direction as the length L1 and the width W1 of the well resistor pattern 104. In this case, the length L2 of the upper resistor pattern 106 may be smaller than the length L1 of the well resistor pattern 104. On the other hand, the width W2 of the upper resistor pattern 106 may be smaller than the width W1 of the well resistor pattern 104 as shown. Alternatively, the width W2 of the upper resistor pattern 106 may be larger than the width W1 of the well resistor pattern 104.

Referring still to FIGS. 1 and 2, highly doped layers 110 may be disposed on the surfaces of the active regions 103a and 103b of the semiconductor substrate 100. The highly doped layers 110 are regions doped with the impurity ions of the same conductive type as the well resistor pattern 104. For example, the well resistor pattern 104 and the highly doped layers 110 may be the N-type impurity diffusion layers. In this case, the highly doped layers 110 may have an impurity concentration higher than that of the well resistor pattern 104. For example, the impurity concentration of the highly doped layers 110 may be equal to that of a source/drain region formed in the cell region.

An interlayer insulating layer 118, which covers the upper resistor pattern 106, is disposed on the semiconductor substrate 100. The interlayer insulating layer 118 may be a silicon oxide layer such as an undoped silicate glass (USG) layer, a boron phosphorous silicate glass (BPSG) layer, a phosphosilicate glass (PSG) layer, or a tetra ethyl orthosilicate (TEOS) layer. The well resistor pattern 104 and the upper resistor pattern 106 are electrically connected to each other through a resistor connector 125 penetrating through the interlayer insulating layer 118. As shown in FIG. 2, the resistor connector 125 may include a first resistor contact plug 120a which contacts a semiconductor surface of the first active region 103a through the interlayer insulating layer 118, a second resistor contact plug 120b which contacts one end portion of the upper resistor pattern 106 adjacent to the first active region 103a through the interlayer insulating layer 118, and a resistor connecting interconnection 124 which is disposed on the interlayer insulating layer 118 to contact upper surfaces of the first and second resistor contact plugs 120a and 120b and connects the first and second resistor contact plugs 120a and 120b to each other. In FIG. 1, the first and second resistor contact, plugs 120a and 120b are formed of two contact plugs, respectively. However, the number of each of the first and second resistor contact plugs 120a and 120b is not limited to this and may be variously modified according to the design rule of the device. That is, the first and second resistor contact plugs 120a and 120b may be formed of a single contact plug or multiple, for example, at least three, contact plugs. The concept of single or multiple contact plugs applies to other embodiments of the present invention described below.

A semiconductor surface of the second active region 103b contacts a first interconnection contact plug 122a which penetrates through the interlayer insulating layer 118, and an upper surface of the first interconnection contact plug 122a contacts a first interconnection 124a disposed on the interlayer insulating layer 118. Also, the other end portion of the upper resistor pattern 106 contacts a second interconnection contact plug 122b which penetrates through the interlayer insulating layer 118, and an upper surface of the second interconnection contact plug 122b contacts a second interconnection 124b disposed on the interlayer insulating layer 118.

As described above, according to the present invention, the upper resistor pattern 106 is disposed on the isolation insulating layer 102 over the well resistor pattern 104. Also, the well resistor pattern 104 and the upper resistor pattern 106 are electrically connected to each other through the resistor connector 125 in series. The well resistor pattern 104 and the upper resistor pattern 106 are connected to each other through the resistor connector 125 in series to form the resistor of the semiconductor device. At this time, the upper resistor pattern 106 overlaps the well resistor pattern 104 to have an area substantially equal to, or smaller than, that of the well resistor pattern 104. As a result, the resistor of the present invention can have a sufficiently large resistance value while having an area smaller than that of a conventional resistor.

On the other hand, temperatures of the well resistor pattern 104 and the upper resistor pattern 106 may increase by Joule's heat generated when the power applied to the resistor including the well resistor pattern 104 and the upper resistor pattern 106 increases. Since the well resistor pattern 104 is formed in the semiconductor substrate 100 having thermal conductivity higher than that of the isolation insulating layer 102, the temperature rise of the well resistor pattern 104 can be stably suppressed. However, in the case of the upper resistor pattern 106 disposed on the isolation insulating layer 102 having relatively low thermal conductivity, heat is not efficiently dissipated and thus the temperature of the upper resistor pattern 106 may increase to beyond a threshold temperature. In this case, an open failure can be generated in the first and second interconnections 124a and 124b by an electro-migration phenomenon that metal atoms in the first and second interconnections 124a and 124b are moved by current. Particularly, in the case where the first and second interconnections 124a and 124b are formed of a metal having a low melting point, such as aluminum, the open failure due to the electro-migration phenomenon may be more serious. However, according to the present invention, the Joule's heat generated in the upper resistor pattern 106 can be efficiently dissipated through the semiconductor substrate having a thermal conductivity parameter that is higher than that of the isolation insulating layer 102 through the second resistor contact plug 120b, the resistor connecting interconnection 124, and the first resistor contact plug 120a. As a result, the temperature rise of the upper resistor pattern 106 can be suppressed to a stable range and thus, the open failure of the interconnection can be prevented.

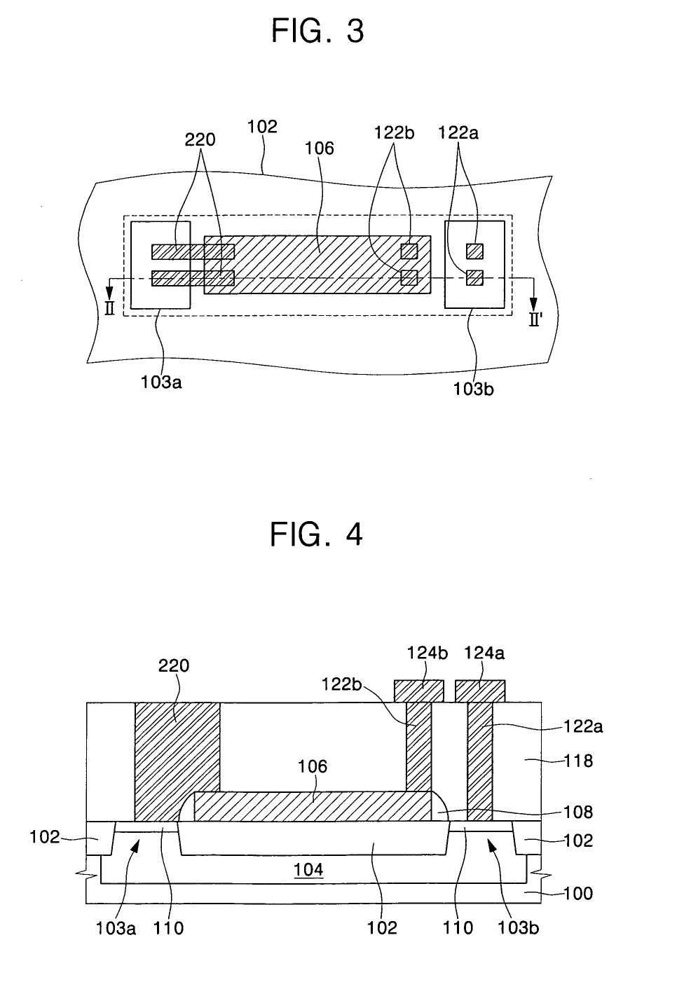

FIG. 3 is a plan view of a semiconductor device including a resistor according to another embodiment of the present invention, and FIG. 4 is a cross-sectional view taken along line II-II′ shown in FIG. 3.

Referring to FIGS. 3 and 4, a resistor connector for connecting a well resistor pattern 104 and an upper resistor pattern 106 is formed of a resistor contact plug 220 which successively contacts a first active region 103a and one end portion of the upper resistor pattern 106 adjacent to the first active region 103a through the interlayer insulating layer 118. In the present embodiment, unlike the embodiment of the present invention described above, the Joule's heat generated in the upper resistor pattern 106 can be more directly transferred to the semiconductor substrate 100 through the resistor contact plug 220, without passing through a resistor connecting interconnection, such as resistor connecting interconnection 124 of FIG. 2. As a result, the Joule's heat generated in the upper resistor pattern 106 can be more efficiently dissipated and thus the temperature rise of the upper resistor pattern 106 can be more reliably suppressed.

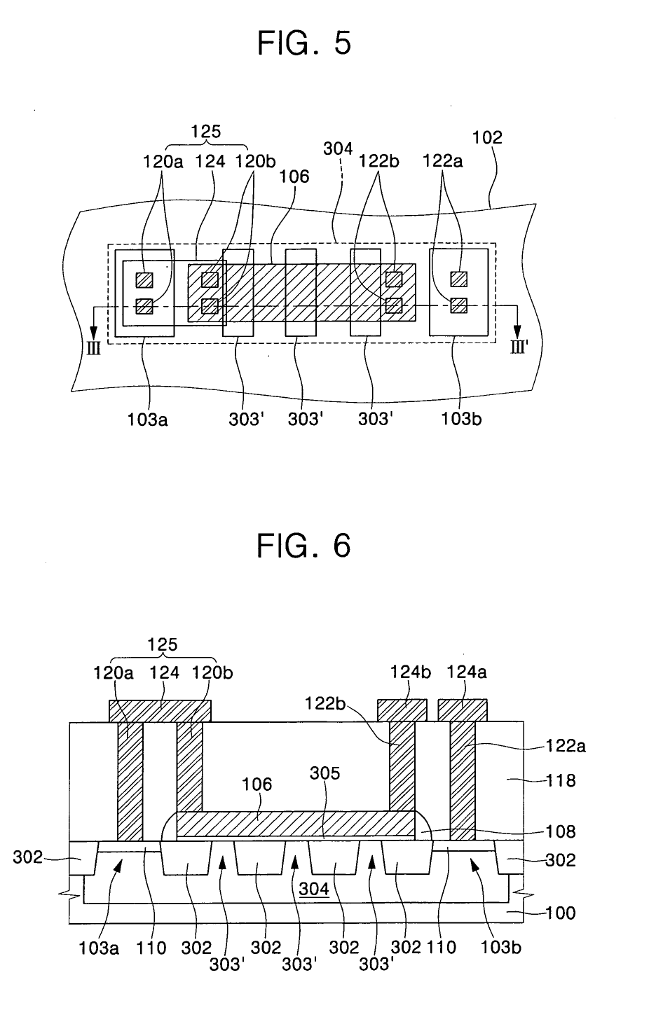

FIG. 5 is a plan view of a semiconductor device including a resistor according to another embodiment of the present invention, and FIG. 6 is a cross-sectional view taken along line III-III′ shown in FIG. 5.

Referring to FIGS. 5 and 6, an isolation insulating layer 302 for defining active regions 103a and 103b and semiconductor regions 303′ between the active regions 103a and 103b is disposed in a semiconductor substrate 100. The active regions 103a and 103b and the semiconductor regions 303′ are connected to each other through the well resistor pattern 304 disposed below the isolation insulating layer 302.

The semiconductor regions 303′ defined by the isolation insulating layer 302 are regions of the top portion semiconductor substrate 100 exposed by the isolation insulating layer 302. An upper resistor pattern 106 may be disposed on the isolation insulating layer 302 between the active regions 103a and 103b to traverse the semiconductor regions 303′. The shape and the number of the semiconductor region 303′ may be variously modified according to a design rule. The upper resistor pattern 106 is electrically insulated from the well resistor pattern 304 by an inter-resistor insulating layer 305 disposed at least on the semiconductor regions 303′. As shown in FIG. 6, the inter-resistor insulating layer 305 may be successively disposed on the isolation insulating layer 302 and the semiconductor regions 303′ to overlap the upper resistor pattern 106. The inter-resistor insulating layer 305 may be formed simultaneously with a gate insulating layer of a MOS transistor formed in a cell region of the semiconductor substrate 100, and formed of a silicon oxide layer, a silicon oxynitride layer, or a high-k dielectric layer.

The semiconductor region 303′ is employed so that the upper resistor pattern 106 has a reproducible shape. Generally, the isolation insulating layer 302 can be formed using a shallow trench isolation (STI) method. At this time, when the isolation insulating layer has a large width between the active regions, a dishing phenomenon can result during a process of forming the isolation insulating layer using the STI method. As a result, the isolation insulating layer 320 can have a concave upper surface. In this case, the upper resistor pattern 106 formed on the isolation insulating layer 305 can not have a reproducible shape due to the variable concave upper surface of the isolation insulating layer, and thus, the actual resistance value may be different from a design value. According to the present embodiment, by defining at least one semiconductor region 303′ between the active regions 103a and 103b, the isolation insulating layer 302 has an adequate narrow width which can suppress the dishing phenomenon from being generated between the active regions 103a and 103b when viewed in the cross-sectional view as shown in FIG. 6. As a result, the upper resistor pattern 106 may have a more stable, and reproducible, shape.

As shown in FIG. 6, the well resistor pattern 304 and the upper resistor pattern 106 may be connected to each other through a resistor connector 125 including a first resistor contact plug 120a, a second resistor contact plug 120b, and a resistor connecting interconnection 124. Alternatively, as shown in FIG. 4, the well resistor pattern 304 and the upper resistor pattern 106 may be connected to each other through a single resistor contact plug which contacts both the first active region 103 and one end portion of the upper resistor pattern 106 through the interlayer insulating layer 118.

Hereinafter, methods of fabricating the semiconductor devices including the resistors according to the embodiments of the present invention will be described.

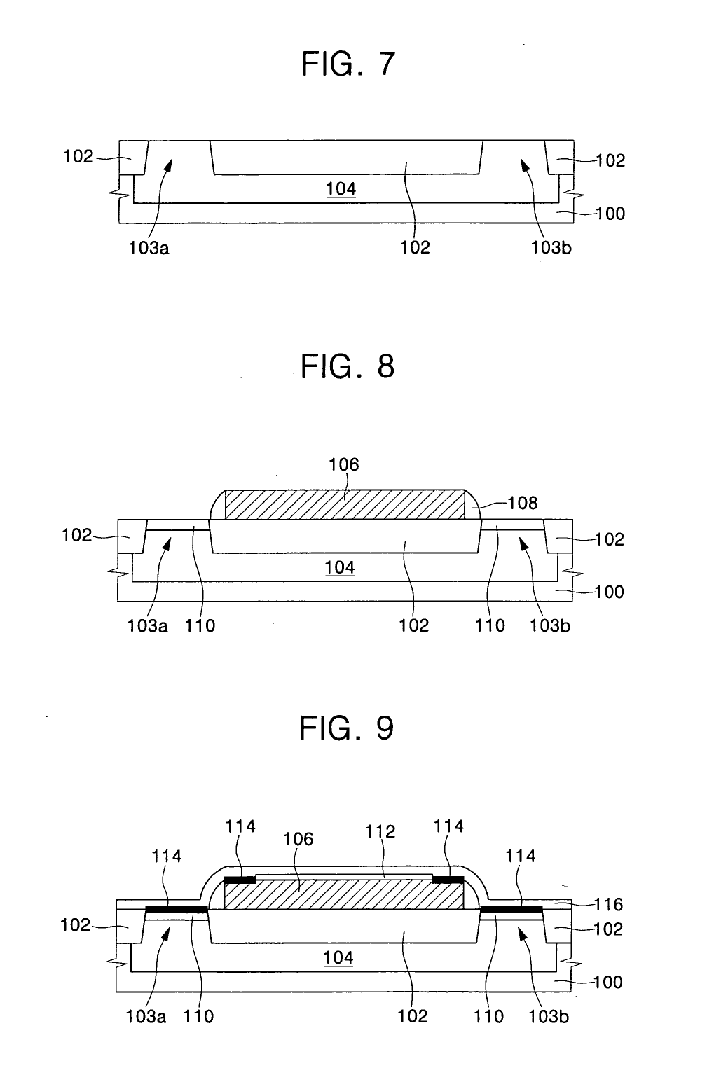

FIGS. 7 through 10 are cross-sectional views illustrating a method of fabricating a semiconductor device including a resistor according to an embodiment of the present invention. FIGS. 7 through 10 are cross-sectional views taken along I-I′ shown in FIG. 1 .

Referring to FIGS. 1 and 7, an isolation insulating layer 102 is formed in a semiconductor substrate 100 to define two active regions 103a and 103b spaced from each other. The semiconductor substrate 100 may be a P-type silicon substrate doped with impurity ions of a first conductivity type, for example, P-type. The isolation insulating layer 102 may be formed of a silicon oxide layer using a STI method. A mask pattern (not shown) exposing the active regions 103a and 103b and the isolation insulating layer 102 therebetween is formed on the semiconductor substrate 100 having the isolation insulating layer 102. The mask pattern may be formed of a photoresist pattern. Thereafter, impurity ions are implanted into the semiconductor substrate 100 using the mask pattern as an ion implantation mask to form a well resistor pattern 104 below the isolation insulating layer 102 and the active region 103a and 103b to connect the active regions 103a and 103b. In this case, the well resistor pattern 104 may be an impurity diffusion layer of a second conductivity type opposite to that of the semiconductor substrate 100. For example, if the semiconductor substrate is a P-type silicon substrate, the well resistor pattern 104 is an N-type impurity diffusion layer. As shown in FIG. 1, the well resistor pattern 104 may have a rectangular shape, but may be formed in other shapes, and is not limited to a rectangular shape. After forming the well resistor pattern 104, the mask pattern is removed. In the case where the mask pattern is the photoresist pattern, the photoresist pattern can be removed by an ashing process using oxygen plasma.

Referring to FIGS. 1 and 8, an upper resistor layer (not shown) is formed on the semiconductor substrate having the well resistor pattern 106. The upper resistor layer may be formed of a polysilicon layer. The polysilicon layer may be doped with N-type or P-type impurity ions by an ion implantation process. Alternatively, the polysilicon layer may be in-situ doped with N-type or P-type impurity ions. Thereafter, the upper resistor layer is patterned to form an upper resistor pattern 106 on the isolation insulating layer 102 between the active regions 103a and 103b. The upper resistor pattern 106 may be formed on the well resistor pattern 104 to have substantially the same shape as the well resistor pattern 104. For example, in the case where the well resistor pattern 104 has the rectangular shape as shown in FIG. 1, the upper resistor pattern 106 also has the rectangular shape. While the upper resistor pattern 106 is formed, a polysilicon gate electrode may be formed in a cell region of the semiconductor substrate 100. On the other hand, before forming the upper resistor layer, an insulating layer (not shown) having a predetermined thickness may be formed on the semiconductor substrate 100. The insulating layer is formed simultaneously with a gate insulating layer of the cell region and may be formed of a silicon oxide layer, a silicon nitride layer, or a high-k dielectric layer.

Insulating spacers 108 may be formed on the sidewalls of the upper resistor pattern 106 through a general spacer forming process. The insulating spacers 108 may be formed of a silicon nitride layer. Next, the impurity ions are implanted into the semiconductor substrate 100 using the upper resistor pattern 106 and the insulating spacers 108 as ion implantation masks. As a result, highly doped layers 110 are formed on the surfaces of the active regions 103a and 103b of the semiconductor substrate. The highly doped layers 110 may be formed together during source/drain ion implantation process of a MOS transistor formed in the cell region of the semiconductor substrate. In this case, the highly doped layers 110 may be an impurity diffusion layer of the same conductivity type as the well resistor pattern 104 and have impurity concentration higher than that of the well resistor pattern 104.

Referring to FIGS. 1 and 9, a silicidation blocking layer 112 is formed to expose both end portions of the upper resistor pattern 106 and to cover the center portion of the upper resistor pattern 106. The silicidation blocking layer 112 may be formed of a silicon nitride layer, or a laminated layer including a silicon oxide layer and a silicon nitride layer. The silicidation blocking layer 112 is formed so as to prevent a metal silicide layer from being formed on the center portion of the upper resistor pattern 106 during a subsequent silicide process. Accordingly, when the silicide process is omitted, the silicidation blocking layer 112 may be omitted. After forming the silicidation blocking layer 112, the silicide process is performed to form metal silicide layers 114 on the both end portions of the upper resistor pattern 106 and the active regions 103a and 103b. The metal silicide layers 114 are formed so as to reduce contact resistance of contact plugs formed in a subsequent process and may be formed of, for example, a cobalt silicide (CoSi₂) layer, a nickel silicide (NiSi₂) layer, a tantalum silicide (TaSi) layer, or a tungsten silicide (WSi) layer. Next, an etch stop layer 116 is conformally formed on the entire surface of the semiconductor substrate having the metal silicide layers 114. The etch stop layer 116 may be formed of, for example, a silicon nitride layer.

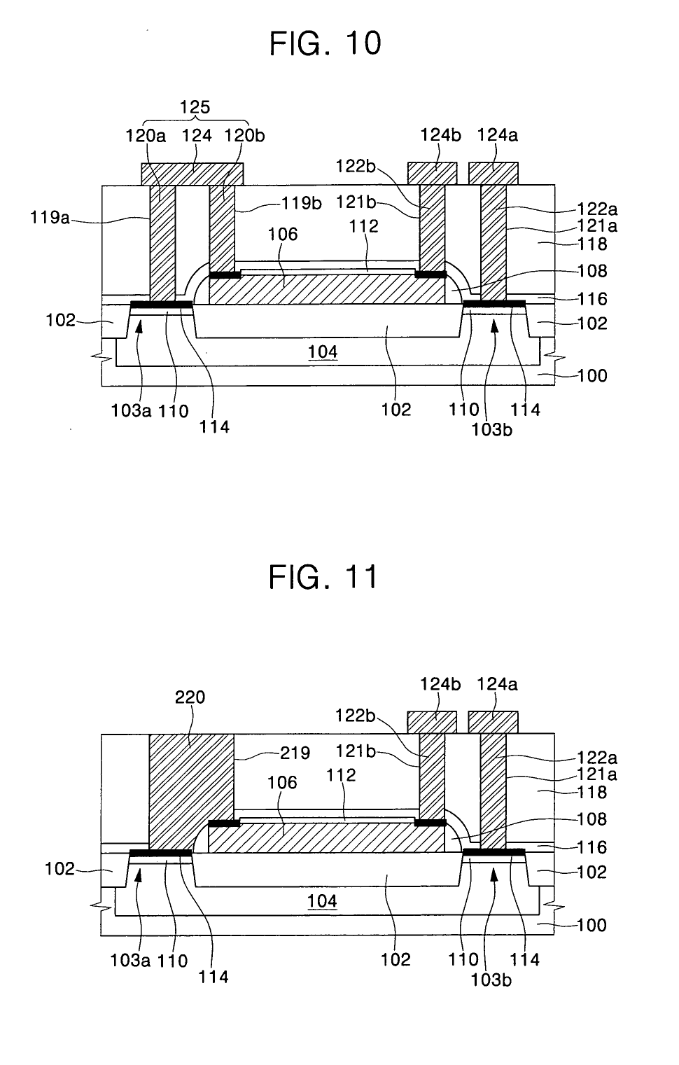

Referring to FIGS. 1 and 10, an interlayer insulating layer 118 is formed on the etch stop layer 116. The interlayer insulating layer 118 may be formed of, for example, a silicon oxide layer such as a USG layer, a BPSG layer, a PSG layer, or a TEOS layer. Next, the interlayer insulating layer 118 and the etch stop layer 116 are sequentially patterned to form a first resistor contact hole 119a exposing one selected from the active regions 103a and 103b, that is, the first active region 103a and a second resistor contact hole 119b exposing one end portion of the upper resistor pattern 106 adjacent to the first active region 103a. Simultaneously, a first interconnection contact hole 121a exposing the second active region 103b and a second interconnection contact hole 121b exposing the other end portion of the upper resistor pattern 106 are formed. When the metal silicide layers 114 are formed, the contact holes 119a, 119b, 121a, and 121b may be formed so as to expose the metal silicide layers 114. Thereafter, a first conductive layer for filling the contact holes 119a, 119b, 121a, and 121b, for example, a tungsten layer, is formed on the entire surface of the semiconductor substrate and a planarization process is performed to form a first resistor contact plug 120a and a second resistor contact plug 120b filling the first resistor hole 119a and the second resistor contact hole 119b, respectively. Simultaneously, a first interconnection contact plug 122a and a second interconnection contact plug 122b filling the first interconnection contact hole 121a and the second interconnection contact hole 121b are formed, respectively. The planarization process may be performed using a chemical mechanical polishing (CMP) method.

Next, a second conductive layer, for example, an aluminum layer, is formed on the interlayer insulating layer 118 having the contact plugs 120a, 120b, 122a, and 122b, and patterned to form a resistor connecting interconnection 124 contacting the upper surfaces of the first resistor contact plug 120a and the second resistor contact plug 120b. Simultaneously, a first interconnection 124a and a second interconnection 124b contacting the upper surfaces of the first interconnection contact plug 122a and the second interconnection contact plug 122b are formed, respectively. The first resistor contact plug 120a, the second resistor contact plug 120b, and the resistor connecting interconnection 124 constitute a resistor connector 125. The well resistor pattern 104 and the upper resistor pattern 106 are connected to each other in series through the resistor connector 125 to form the resistor of the semiconductor device.

FIG. 11 is a cross-sectional view illustrating a method of fabricating a semiconductor device including a resistor according to another embodiment of the present invention. FIG. 11 is a cross-sectional view taken along line II-II′ of FIG. 3.

Referring to FIGS. 3 and 11, after the processes illustrated in FIGS. 7 through 9 are performed, the interlayer insulating layer 118 and the etch stop layer 116 are patterned to form a resistor contact hole 219 which successively exposes one selected from the active regions 103a and 103b, for example, the active region 103a and one end portion of the upper resistor pattern 106 adjacent to the first active region 103a. Simultaneously, the first interconnection contact hole 121a and the second interconnection contact hole 121b as illustrated in FIG. 10 are formed. Thereafter, a resistor contact plug 220, a first interconnection contact plug 122a, and a second interconnection contact plug 122b, which fill the resistor contact hole 219, the first interconnection contact hole 121a, and the second interconnection contact hole 121b, respectively, are formed. According to the present embodiment, the well resistor pattern 104 and the upper resistor pattern 106 are connected to each other in series through the resistor connector 220.

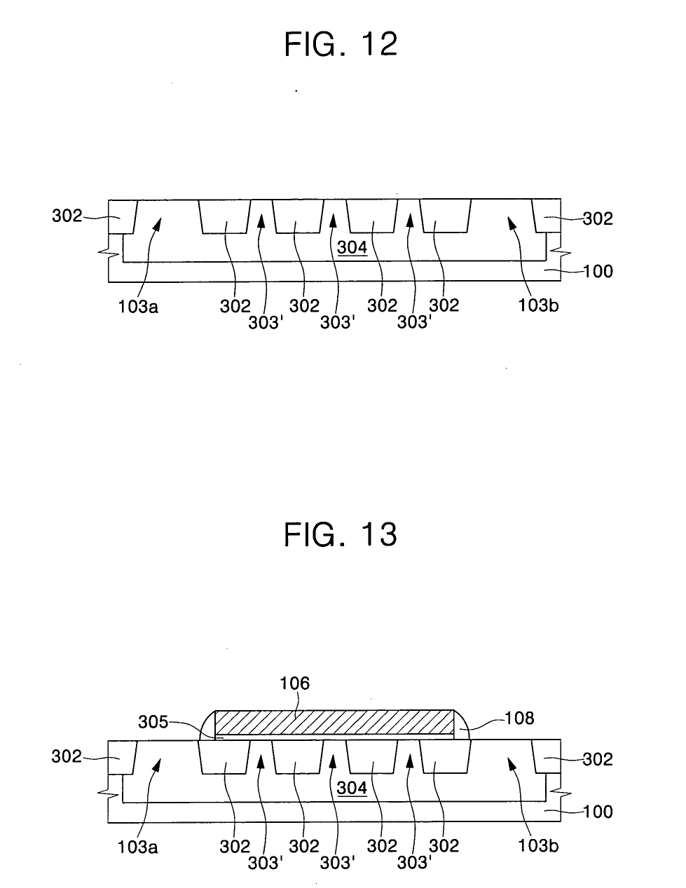

FIGS. 12 and 13 are cross-sectional views illustrating a method of fabricating a semiconductor device including a resistor according to another embodiment of the present invention. FIGS. 12 and 13 are cross-sectional views taken along line III-III′ of FIG. 5.

Referring to FIGS. 5 and 12, an isolation insulating layer 302 is formed in the semiconductor substrate 100 to define a pattern of active regions 103a and 103b spaced from each other and semiconductor regions 303′ therebetween. The isolation insulating layer 302 may be formed using a general STI method. The semiconductor regions 303′ are regions of the semiconductor substrate exposed by the isolation insulating layer 302, and the number and the shape of the semiconductor regions 303′ defined between the active regions 103a and 103b may be variously modified according to a design rule. As described above, the semiconductor regions 303′ located between the active regions 103a and 103b are formed so as to prevent a dishing phenomenon that causes the isolation insulating layer to have a concave upper surface while performing the STI method. Next, an ion implantation process is performed to form a well resistor pattern 304.

Referring to FIGS. 5 and 13, an inter-resistor insulating layer 305 is formed on the semiconductor substrate having the isolation insulating layer 302. The inter-resistor insulating layer 305 may be formed simultaneously with a gate insulating layer of a MOS transistor formed in a cell region of the semiconductor substrate. The inter-resistor insulating layer 305 may be formed of a silicon oxide layer, a silicon oxynitride layer, or a high-k dielectric layer. Thereafter, an upper resistor pattern 106 which traverses the semiconductor region 303′ is formed on the isolation insulating layer 304 between the active regions 103a and 103b. The upper resistor pattern 106 and the well resistor pattern 304 are electrically insulated from each other by the isolation insulating layer 302 and the inter-resistor insulating layer 305.

Thereafter, the contact plugs and the interconnections are formed through the processes illustrated in FIGS. 8 through 10 or FIG. 11 and thus the semiconductor device including the resistor having the well resistor pattern 304 and the upper resistor pattern 106 is manufactured.

As described above, according to the present invention, the upper resistor pattern which is electrically insulated from the well resistor pattern is formed on the well resistor pattern, and the upper resistor pattern and the well resistor pattern are electrically connected to each other in series to form the resistor. As a result, the semiconductor device including the resistor having a sufficiently large resistance value can be manufactured while having a reduced chip occupation area.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A semiconductor device comprising:
an isolation insulating layer disposed in a semiconductor substrate to define at least two active regions spaced from each other;
a well resistor pattern disposed below the isolation insulating layer to connect the active regions;
an upper resistor pattern disposed on the isolation insulating layer between the active regions; and
a resistor connector electrically connecting a selected one of the active regions with the upper resistor pattern so that the well resistor pattern and the upper resistor pattern are connected in series.

2. The device according to claim 1, wherein the well resistor pattern is an impurity diffusion layer doped with N-type or P-type impurity ions.

3. The device according to claim 1, wherein the upper resistor pattern is a polysilicon layer pattern.

4. The device according to claim 3, wherein the polysilicon layer pattern is doped with N-type or P-type impurity ions.

5. The device according to claim 3, wherein the upper resistor pattern is formed simultaneously with a polysilicon gate electrode.

6. The device according to claim 1, wherein the well resistor pattern has a rectangular shape having a length corresponding to a distance between the active regions and a width perpendicular to the length when viewed in a plan view.

7. The device according to claim 6, wherein the upper resistor pattern is disposed over the well resistor pattern and has a rectangular shape extending in a same length direction and width direction as the well resistor pattern when viewed in a plan view.

8. The device according to claim 1, further comprising at least one semiconductor region defined between the active regions by the isolation insulating layer.

9. The device according to claim 8, wherein the active regions and the at least one semiconductor region are connected to each other through the well resistor pattern.

10. The device according to claim 8, further comprising an inter-resistor insulating layer disposed on the semiconductor substrate of the semiconductor region to electrically insulate the upper resistor pattern from the well resistor pattern.

11. The device according to claim 1, further comprising an interlayer insulating layer disposed on the semiconductor substrate to cover the upper resistor pattern, wherein the resistor connector is disposed to penetrate through the interlayer insulating layer.

12. The device according to claim 11, wherein the resistor connector comprises a resistor contact plug which contacts both the selected one of the active regions and one end portion of the upper resistor pattern adjacent to the selected one of the active regions through the interlayer insulating layer.

13. The device according to claim 11, wherein the resistor connector comprises a first resistor contact plug which contacts the selected one of the active regions through the interlayer insulating layer, a second resistor contact plug which contacts one end portion of the upper resistor pattern adjacent to the selected one of the active regions through the interlayer insulating layer, and a resistor connecting interconnection which is disposed on the interlayer insulating layer to connect the first and second resistor contact plugs.

14. The device according to claim 11, further comprising a first interconnection contact plug which contacts the other of the active regions through the interlayer insulating layer and a second interconnection contact plug which contacts the other end portion of the upper resistor pattern through the interlayer insulating layer.

15. The device according to claim 14, further comprising a first interconnection and a second interconnection disposed on the interlayer insulating layer to contact the first interconnection contact plug and the second interconnection contact plug, respectively.

16. The device according to claim 1, further comprising highly doped layers disposed on the surfaces of the active regions of the semiconductor substrate and doped with impurity ions of the same conductivity type as the well resistor pattern, wherein a concentration of the highly doped layers is higher than that of the well resistor pattern.

17. A method of fabricating a semiconductor device, comprising:
forming an isolation insulating layer to define at least two active regions spaced from each other in a semiconductor substrate;
forming a well resistor pattern in the semiconductor substrate below the isolation insulating layer to connect the active regions;
forming an upper resistor pattern on the isolation insulating layer between the active regions; and
forming a resistor connector electrically connecting a selected one of the active regions with one end portion of the upper resistor pattern adjacent to the selected one of the active regions so that the well resistor pattern and the upper resistor pattern are connected in series.

18. The method according to claim 17, wherein forming the well resistor pattern comprises:
forming a mask pattern exposing the active regions and the isolation insulating layer between the active regions on the semiconductor substrate; and
implanting impurity ions into the semiconductor substrate using the mask pattern as an ion implantation mask.

19. The method according to claim 17, wherein the impurity ions are N-type or P-type impurity ions.

20. The method according to claim 17, wherein the upper resistor pattern is formed of a polysilicon layer pattern.

21. The method according to claim 20, wherein the polysilicon layer pattern is doped with N-type or P-type impurity ions.

22. The method according to claim 20, wherein the upper resistor pattern is formed simultaneously with a polysilicon gate electrode.

23. The method according to claim 17, wherein the well resistor pattern has a rectangular shape having a length corresponding to a distance between the active regions and a width perpendicular to the length when viewed in a plan view.

24. The method according to claim 23, wherein the upper resistor pattern is formed over the well resistor pattern and has a rectangular shape extending in the same length direction and width direction as the well resistor pattern when viewed in a plan view.

25. The method according to claim 17, wherein forming the isolation insulating layer further comprises defining at least one semiconductor region between the active regions.

26. The method according to claim 25, wherein the active regions and the at least one semiconductor region are connected to each other through the well resistor pattern.

27. The method according to claim 25, before forming the well resistor pattern, further comprising forming an inter-resistor insulating layer on the semiconductor substrate of the semiconductor region to electrically insulate the upper resistor pattern from the well resistor pattern.

28. The method according to claim 17, after forming the upper resistor pattern, further comprising forming an interlayer insulating layer on the semiconductor substrate to cover the upper resistor pattern, wherein the resistor connector is formed through the interlayer insulating layer.

29. The method according to claim 28, wherein forming the resistor connector comprises:
patterning the interlayer insulating layer to form a resistor contact hole exposing both the selected one of the active regions and one end portion of the upper resistor pattern adjacent to the selected one of the active regions; and
forming a resistor contact plug filling the resistor contact hole.

30. The method according to claim 28, wherein forming the resistor connector comprises:
patterning the interlayer insulating layer to form a first resistor contact hole and a second resistor contact hole exposing the selected one of the active regions and one end portion of the upper resistor pattern adjacent to the selected one of the active regions, respectively;
forming a first resistor contact plug and a second resistor contact plug filling the first resistor contact hole and the second resistor contact hole, respectively; and
forming a resistor connecting interconnection on the interlayer insulating layer to connect the first resistor contact plug with the second resistor contact plug.

31. The method according to claim 28, further comprising simultaneously forming a first interconnection contact plug which contacts the other one of the active regions through the interlayer insulating layer and a second interconnection contact plug which contacts the other end portion of the upper resistor pattern through the interlayer insulating layer, when forming the resistor connector.

32. The method according to claim 17, after forming the upper resistor pattern, further comprising:
forming insulating spacers to cover sidewalls of the upper resistor pattern; and
forming highly doped layers which are doped with impurity ions of the same conductivity type as the well resistor pattern and have an impurity concentration higher than that of the well resistor pattern in the surfaces of the active regions of the semiconductor substrate.
